(19) United States
(12) Patent Application Publication
(10) Pub. No.: US 2005/0101065 A1
(43) Pub. Date: May 12, 2005

(54) Method of manufacturing a semiconductor device

(76) Inventor: Susumu Inoue, Sakata-shi (JP)

Correspondence Address: HARNESS, DICKEY & PIERCE, P.L.C., P.O. BOX 828, BLOOMFIELD HILLS, MI, 48303, US

(21) Appl. No.: 10/956,005

(22) Filed: Sep. 30, 2004

(30) Foreign Application Priority Data
Oct. 1, 2003 (JP) 2003-342899

(51) Int. Cl. H01L 21/00; H01L 21/84; H01L 21/336

(52) U.S. Cl. 438/149

(57) ABSTRACT

A method of manufacturing a semiconductor device includes: a step of forming a bottom oxide film on a silicon substrate in a memory transistor formation region and a peripheral circuit transistor formation region; a step of forming a nitride film on the bottom oxide film; a step of forming a top oxide film on the nitride film; a step of removing the top oxide film, the nitride film and the bottom oxide film from the peripheral circuit transistor formation region to expose a surface of the silicon substrate in the peripheral circuit transistor formation region; and a step of forming a gate oxide film on the silicon substrate in the peripheral circuit transistor formation region.

### RELATED APPLICATIONS

This application claims priority to Japanese Patent Application No. 2003-342899 filed Oct. 1, 2003 which is hereby expressly incorporated by reference herein in its entirety.

### BACKGROUND

1. Field of the Invention

The present invention relates to a method of manufacturing a semiconductor device, and in particular relates to a method of manufacturing a semiconductor device that can shorten the manufacturing process.

2. Related Art

The following describes a method of manufacturing a conventional non-volatile semiconductor device. This method of manufacturing a non-volatile semiconductor device is disclosed in Japanese Unexamined Patent Publication No. 2001-189390.

A memory transistor formation region and a peripheral circuit transistor formation region are isolated on a silicon substrate and ONO (Oxide-Nitride-Oxide) films are formed on the entire surface of the silicon substrate. Next, a gate electrode is formed on the ONO films in the memory transistor formation region. This gate electrode and the ONO films construct a dielectric gate structure.

Next, the ONO films are removed from the peripheral circuit transistor formation region to expose the silicon substrate. After this, a gate oxide film is formed on the silicon substrate in the peripheral circuit transistor formation region, and the gate electrode is formed on the gate oxide film. Next, impurities are introduced into source and drain regions in the memory transistor formation region and the peripheral circuit transistor formation region, respectively, and a heat treatment is carried out to form diffused layers for the source and drain regions.

However, in the above conventional semiconductor device, the gate electrodes of the memory transistor formation region and the peripheral circuit transistor formation region are formed by separate processes. This makes the manufacturing process long and complex.

The present invention was conceived in view of the above problem, and it is an object of the present invention to provide a method of manufacturing a semiconductor device that can shorten and simplify the manufacturing process.

### SUMMARY

To solve the stated problem, a method of manufacturing a semiconductor device according to the present invention includes:
a step of forming a bottom oxide film on a semiconductor substrate in a memory transistor formation region and a peripheral circuit transistor formation region, respectively;
a step of forming a nitride film on the bottom oxide film;
a step of forming a top oxide film on the nitride film;
a step of removing the top oxide film, the nitride film and the bottom oxide film from the peripheral circuit transistor formation region to expose a surface of the semiconductor substrate in the peripheral circuit transistor formation region; and
a step of forming a gate insulating film on the semiconductor substrate in the peripheral circuit transistor formation region.

According to the above method of manufacturing a semiconductor device, a bottom oxide film, a nitride film, and a top oxide film are formed on a semiconductor substrate in a memory transistor formation region and a peripheral circuit transistor formation region. The top oxide film, the nitride film, and the bottom oxide film are removed from the peripheral circuit transistor formation region, and then a gate insulating film is formed on the semiconductor substrate in the peripheral circuit transistor formation region. This means that the process can be shortened as compared to the related art, and as a result, the manufacturing cost can be reduced.

Another method of manufacturing a semiconductor device according to the present invention includes:
a step of forming a sacrificial oxide film on a semiconductor substrate in a memory transistor formation region and a peripheral circuit transistor formation region, respectively;
a step of removing the sacrificial oxide film from the memory transistor formation region and leaving the sacrificial oxide film in the peripheral circuit transistor formation region;
a step of forming a bottom oxide film on the semiconductor substrate in the memory transistor formation region and on the sacrificial oxide film in the peripheral circuit transistor formation region, respectively;
a step of forming a nitride film on the bottom oxide film;
a step of forming a top oxide film on the nitride film;
a step of etching and removing the top oxide film, etching and removing the nitride film, and etching and removing the bottom oxide film with the sacrificial oxide film from the peripheral circuit transistor formation region to expose a surface of the semiconductor substrate in the peripheral circuit transistor formation region; and
a step of forming a gate insulating film on the semiconductor substrate in the peripheral circuit transistor formation region.

According to the above method of manufacturing a semiconductor device, a bottom oxide film, a nitride film, and a top oxide film are formed on a semiconductor substrate in a memory transistor formation region and on a sacrificial oxide film in a peripheral circuit transistor formation region. The top oxide film, the nitride film, the bottom oxide film, and the sacrificial oxide film are etched and removed from the peripheral circuit transistor formation region. Next, a gate insulating film is formed on the semiconductor substrate in the peripheral circuit transistor formation region, so that the process can be shortened as compared to the related art, and as a result, the manufacturing cost can be reduced. Also, when etching and removing the nitride film from the peripheral circuit transistor formation region, even if holes are produced in the bottom oxide film by a partial etching of the bottom oxide film due to the etching selection ratio not being set sufficiently high, the sacrificial oxide film will remain below the bottom oxide film, so that the semiconductor substrate does not become exposed and etching of the semiconductor substrate is prevented. By doing so, it becomes possible to etch the nitride film even if the etching selection ratio is not set sufficiently high.

Also, the method of manufacturing a semiconductor device according to the present invention may further include, between the step of forming the bottom oxide film and the step of forming the nitride film, a step of carrying out a heat treatment in an NH₃ atmosphere.

The method of manufacturing a semiconductor device according to the present invention may further include, after the step of forming the gate insulating film on the semiconductor substrate, a step of forming a first gate electrode on the top oxide film in the memory transistor formation region and forming a second gate electrode on the gate insulating film in the peripheral circuit transistor formation region.

The method of manufacturing a semiconductor device according to the present invention may further include, after the step of forming the gate insulating film on the semiconductor substrate, a step of forming a polysilicon film on the top oxide film in the memory transistor formation region and the gate insulating film in the peripheral circuit transistor formation region, respectively, and patterning the polysilicon film to form a first gate electrode composed of the polysilicon film on the top oxide film in the memory transistor formation region, and form a second gate electrode composed of the polysilicon film on the gate insulating film in the peripheral circuit transistor formation region.

The method of manufacturing a semiconductor device according to the present invention may further include, after the step of forming the second gate electrode on the gate insulating film, a step of forming source and drain regions in the semiconductor substrate on both sides of and below the first gate electrode and the second gate electrode, respectively.

The method of manufacturing a semiconductor device according to the present invention may further include, after the step of forming the second gate electrode on the gate insulating film, a step of forming LDD regions in the semiconductor substrate on both sides of and below the first gate electrode and the second gate electrode, respectively, and forming source and drain regions in the semiconductor substrate at positions outside the LDD regions.

Another method of manufacturing a semiconductor device according to the present invention includes:
a step of forming ONO films on a semiconductor substrate in a memory transistor formation region and a peripheral circuit transistor formation region, respectively;
a step of removing the ONO films in the peripheral circuit transistor formation region to expose a surface of the semiconductor substrate in the peripheral circuit transistor formation region; and
a step of forming a gate insulating film on the semiconductor substrate in the peripheral circuit transistor formation region.

According to the above method of manufacturing a semiconductor device, ONO films are formed on the semiconductor substrate in a memory transistor formation region and a peripheral circuit transistor formation region. The ONO films are removed from only the peripheral circuit transistor formation region. Then a gate insulating film is formed on the semiconductor substrate in the peripheral circuit transistor formation region. This means that the process can be shortened as compared to the related art, and as a result, the manufacturing cost can be reduced.

Another method of manufacturing a semiconductor device according to the present invention includes:
a step of forming a sacrificial oxide film on a semiconductor substrate in a memory transistor formation region and a peripheral circuit transistor formation region, respectively;
a step of removing the sacrificial oxide film in the memory transistor formation region and leaving the sacrificial oxide film in the peripheral circuit transistor formation region;
a step of forming ONO films on the semiconductor substrate in the memory transistor formation region and on the sacrificial oxide film in the peripheral circuit transistor formation region, respectively;
a step of etching and removing the ONO films and the sacrificial oxide film in the peripheral circuit transistor formation region to expose a surface of the semiconductor substrate in the peripheral circuit transistor formation region; and
a step of forming a gate insulating film on the semiconductor substrate in the peripheral circuit transistor formation region.

### BRIEF DESCRIPTION OF THE DRAWINGS

FIGS. 1A to 1C are cross-sectional views showing a method of manufacturing a non-volatile semiconductor device according to a first embodiment of the present invention.

FIGS. 2D to 2F are cross-sectional views showing a method of manufacturing a non-volatile semiconductor device according to the first embodiment of the present invention.

FIGS. 3G and 3H are cross-sectional views showing a method of manufacturing a non-volatile semiconductor device according to the first embodiment of the present invention.

FIGS. 4A to 4C are cross-sectional views showing a method of manufacturing a non-volatile semiconductor device according to a second embodiment of the present invention.

FIGS. 5D to 5F are cross-sectional views showing a method of manufacturing a non-volatile semiconductor device according to the second embodiment of the present invention.

### DETAILED DESCRIPTION

The following describes embodiments of the present invention with reference to the attached drawings.

### First Embodiment

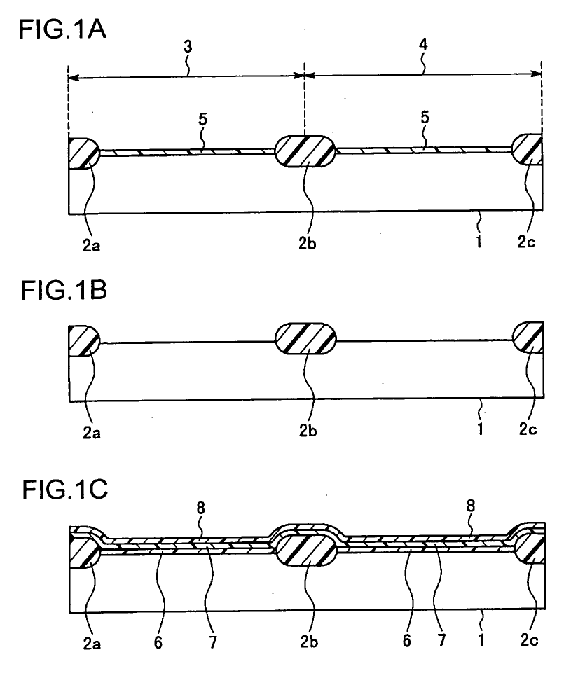

FIG. 1A to FIG. 3H are cross-sectional views that show a method of manufacturing a non-volatile semiconductor device according to a first embodiment of the present invention. The non-volatile semiconductor device is a MONOS (Metal-Oxide-Nitride-Oxide Semiconductor)-type flash memory.

First, as shown in FIG. 1A, isolating/insulating films 2a to 2c composed of silicon oxide films are formed on a P-type silicon substrate 1 by LOCOS (LOCal Oxidation of Silicon), for example. Here, an active region in the upper-left part of FIG. 1A that is isolated by the isolating/insulating film 2b is a memory transistor formation region 3, and an active region in an upper-right part of FIG. 1A is a peripheral circuit transistor formation region 4. Next, a sacrificial oxide film 5 is formed on the surface of the silicon substrate 1 by thermal oxidization.

After this, as shown in FIG. 1B, the sacrificial oxide film 5 is removed by lightly etching the entire surface of the silicon substrate 1.

Next, as shown in FIG. 1C, a bottom oxide film 6 composed of a silicon oxide film that is 3.8 nm thick, for example, is formed on the surface of the silicon substrate 1. The bottom oxide film 6 is formed by thermal oxidization for around 120 seconds at a temperature between about 1000 to 1150° C., and preferably 1100° C. in a dry oxygen atmosphere at a pressure of about 760 Torr. Alternatively, the bottom oxide film 6 may be formed by thermal oxidization in a wet oxide atmosphere at a temperature between about 650 to 900° C., and more preferably in a range of 750 to 850° C.

Next, annealing is carried out at a temperature between about 650 to 950° C. for a period of about several minutes to two hours in an NH₃ atmosphere. Next, a nitride film (Si₃N₄) 7 that is 5.0 nm thick, for example, is deposited on the bottom oxide film 6 by low-pressure CVD (Chemical Vapor Deposition). After this, a top oxide film (HTO) 8 composed of a silicon oxide film that is 4.0 nm thick, for example, is formed on the nitride film 7 by low-pressure CVD at a comparatively high temperature. In this way, ONO films (the bottom oxide film—the nitride film—the top oxide film) are formed on the silicon substrate 1.

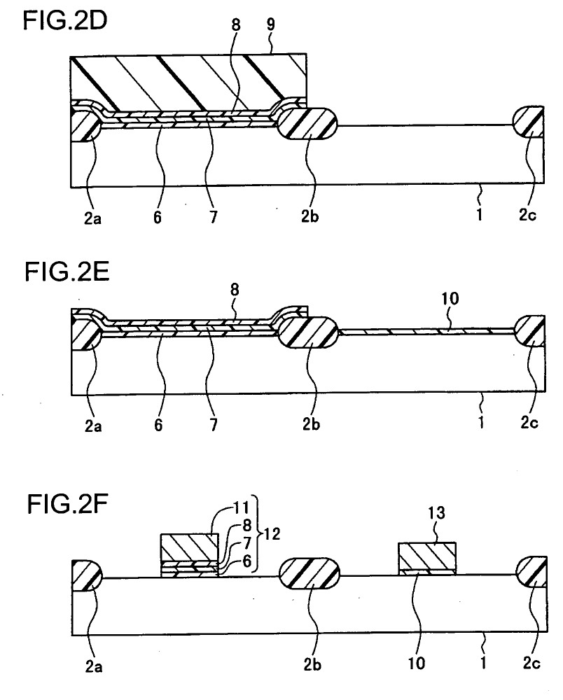

After this, as shown in FIG. 2D, a photoresist film is applied onto the top oxide film 8 and by exposing and developing the photoresist film, a resist pattern 9 is formed on the top oxide film 8. This resist pattern 9 is a pattern that covers the memory transistor formation region 3.

Next, the top oxide film 8 is subjected to dry etching with the resist pattern 9 as a mask to remove the top oxide film 8 from the peripheral circuit transistor formation region 4. After this, by dry etching the nitride film 7 with the resist pattern 9 as a mask, the nitride film 7 in the peripheral circuit transistor formation region 4 is removed. Next, by wet etching with the resist pattern 9 as a mask, the bottom oxide film 6 in the peripheral circuit transistor formation region is removed. In this way, the ONO films in the peripheral circuit transistor formation region are removed.

Next, as shown in FIG. 2E, the resist pattern 9 is removed, and a gate oxide film 10 is formed on the surface of the silicon substrate 1 in the peripheral circuit transistor formation region 4 by thermal oxidization. In this way, ONO films are formed on the entire surface of the silicon substrate 1, the ONO films in only the peripheral circuit transistor formation region 4 are removed, and then the gate oxide film 10 is formed in the peripheral circuit transistor formation region, as compared to the related art, the process is shortened.

As shown in FIG. 2F, a polysilicon film is then deposited on the entire surface including the top oxide film 8 and the gate oxide film 10 by CVD. Next, a photoresist layer, not shown, is formed on the polysilicon film. The photoresist layer is exposed and developed to form a resist pattern on the polysilicon film. After this, by patterning the polysilicon film with the resist pattern as a mask, a gate electrode 11 is formed on the ONO films in the memory transistor formation region, and a gate electrode 13 is formed on the gate oxide film 10 in the peripheral circuit transistor formation region. In this way, a dielectric gate structure 12 composed of the bottom oxide film 6, the nitride film 7, the top oxide film 8, and the gate electrode 11 is formed in the memory transistor formation region, and the gate electrode 13 of a transistor is formed in the peripheral circuit transistor formation region.

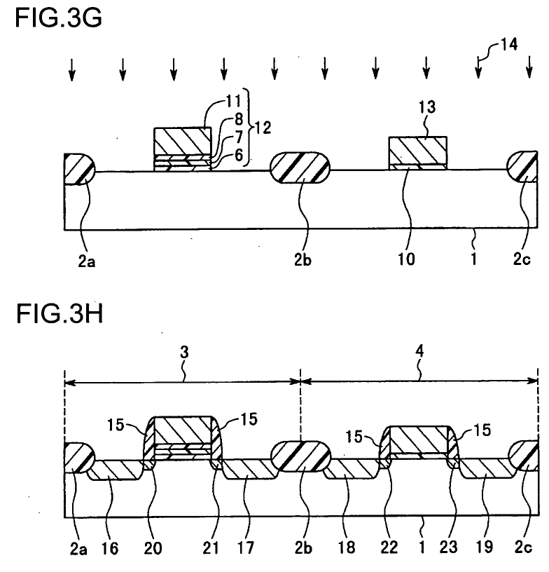

After this, as shown in FIG. 3G, ion injection of a low concentration dopant 14 into the silicon substrate 1 is carried out with the dielectric gate structure 12 and the gate electrode 13 as a mask. By doing so, the low concentration dopant is introduced into LDD (Lightly Doped Drain) regions in the memory transistor formation region and the peripheral circuit transistor formation region.

Next, as shown in FIG. 3H, a silicon oxide layer is deposited on the entire surface including the dielectric gate structure 12 and the gate electrode 13 by CVD. After this, by etching back this silicon oxide film, side walls 15 are formed on both side surfaces of the dielectric gate structure 12 and the gate electrode 13, respectively.

After this, ion injection of a high-concentration dopant into the silicon substrate 1 is carried out with the dielectric gate structure 12, the gate electrode 13, and the side walls 15 as a mask, and a heat treatment is carried out to diffuse the dopant. By doing so, diffused layers 16, 17 (source and drain regions) that are high-concentration doped regions are formed in the silicon substrate 1 on both sides of the dielectric gate structure 12 in the memory transistor formation region 3 and diffused layers 20, 21 (LDD regions) that are low-concentration doped regions are formed inside these diffused layers. Also, diffused layers 18, 19 (source and drain regions) that are high-concentration doped regions are formed in the silicon substrate 1 on both sides of the gate electrode 13 in the peripheral circuit transistor formation region 4, and diffused layers 22, 23 (LDD regions) that are low-concentration doped regions are formed inside these diffused layers.

Next, the operation of a MONOS-type flash memory with the above construction will be described.

In the memory transistor formation region 3, the ONO films have a function for storing a charge in a charge trap inside the nitride film 7 and a charge trap formed at the interface between the nitride film 7 and the top oxide film 8. By applying a suitable voltage to the gate electrode 11, the diffused layers 16, 17 that are the source and drain regions in the silicon substrate 1, and the silicon substrate 1 itself, a tunnel current is generated so that electrons are injected into the ONO films from the silicon substrate 1 via the bottom oxide film 6, conducted by the electric field formed by the above voltage, and captured by the trap level. Alternatively, electrons are conversely emitted from the ONO films to the silicon substrate 1 via the bottom oxide film 6.

According to the first embodiment, ONO films are formed on the entire surface of the silicon substrate 1, the ONO films are removed from only the peripheral circuit transistor formation region 4, and the gate oxide film 10 is formed in the surface of the silicon substrate 1 in the peripheral circuit transistor formation region 4. For this reason, the process can be shortened as compared to the related art, and as a result, a reduction in manufacturing cost can be realized. In the related art, the ONO films and the gate electrode 11 are formed in the memory transistor formation region, the ONO films of the peripheral circuit transistor formation region are removed, and then the gate oxide film and the gate electrode are formed in the peripheral circuit transistor formation region. In the present embodiment however, as described above, after the ONO films have been formed in the peripheral circuit transistor formation region and the gate oxide film has been formed in the memory transistor formation region, the gate electrodes are simultaneously formed on the ONO films and the gate oxide film.

### Second Embodiment

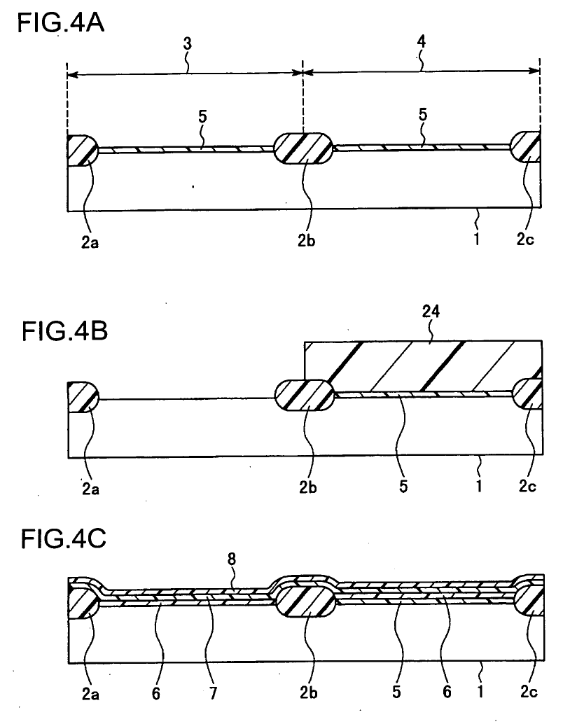

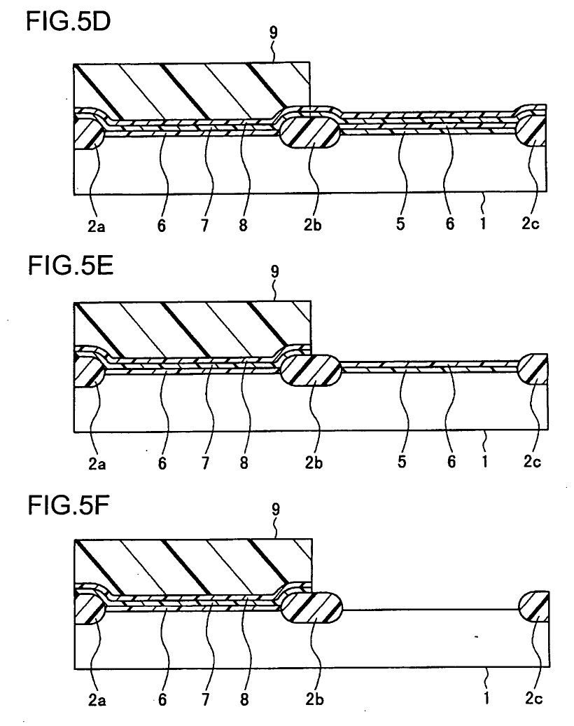

FIG. 4A to FIG. 5F are cross-sectional views showing a method of manufacturing a non-volatile semiconductor device according to a second embodiment of the present invention. Parts that are the same as in FIG. 1A to FIG. 3H have been assigned the same reference numerals.

As shown in FIG. 4A, the isolating/insulating films 2a to 2c composed of silicon oxide films are formed on a P-type silicon substrate 1 by LOCOS, for example. Next, the sacrificial oxide film 5 is formed on the surface of the silicon substrate 1 by thermal oxidization.

Next, as shown in FIG. 4B, a photoresist film is applied onto the entire surface including the sacrificial oxide film 5, and the photoresist layer is exposed and developed to form a resist pattern 24 that covers the peripheral circuit transistor formation region 4 on the sacrificial oxide film 5. After this, the sacrificial oxide film 5 in the memory transistor formation region 3 is removed by light etching with the resist pattern 24 as a mask.

After this, as shown in FIG. 4C, the resist pattern 24 is removed and ONO films are formed on the entire surface.

That is, the bottom oxide film 6 composed of a silicon oxide film that is 3.8 nm thick, for example, is formed on the surface of the silicon substrate 1 in the memory transistor formation region 3 and on the sacrificial oxide film 5 in the peripheral circuit transistor formation region 4. The method of forming the bottom oxide film 6 is the same as in the first embodiment. After this, annealing is carried out at a temperature between about 650 to 950° C. for a period of about several minutes to two hours in an NH₃ atmosphere. At this time, the peripheral circuit transistor formation region is covered with the sacrificial oxide film 5 and so is not easily affected by the NH₃ and the like. Next, the nitride film (Si₃N₄) 7 that is 5.0 nm thick, for example, is deposited on the bottom oxide film 6 by low-pressure CVD. After this, the top oxide film (HTO) 8 composed of a silicon oxide film that is 4.0 nm thick, for example, is formed on the nitride film 7 by low-pressure CVD at a comparatively high temperature. By doing so, ONO films (the bottom oxide film—the nitride film—the top oxide film) are formed on the silicon substrate 1.

After this, as shown in FIG. 5D, the resist pattern 9 that covers the memory transistor formation region 3 on the top oxide film 8 is formed.

Next, as shown in FIG. 5E, the top oxide film 8 is subjected to dry etching with the resist pattern 9 as a mask to remove the top oxide film 8 in the peripheral circuit transistor formation region.

Next, by dry etching the nitride film 7 with the resist pattern 9 as a mask, the nitride film 7 in the peripheral circuit transistor formation region is removed. At this time, as the dry etching conditions, it is normally preferable to use conditions whereby the etching selection ratio for the etching selection ratio nitride film 7 and the bottom oxide film 6 is sufficiently high so that the bottom oxide film 6 is not etched. However, in the present embodiment, the nitride film 7 can be etched even without setting a high etching selection ratio. That is, if the nitride film 7 is etched without setting a high etching selection ratio, part of the bottom oxide film 6 will be etched together with the nitride film 7, but since the sacrificial oxide film 5 remains below the bottom oxide film in the peripheral circuit transistor formation region, it is possible to prevent the silicon substrate from becoming exposed and from being etched even if there are holes in the bottom oxide film. Accordingly, since the magnitude of the etching selection ratio is not especially important, it is possible to increase the margin of the etching conditions, which facilitates the etching process.

After this, as shown in FIG. 5F, by wet etching with the resist pattern 9 as a mask, the bottom oxide film 6 and the sacrificial oxide film 5 in the peripheral circuit transistor formation region are removed. By doing so, the ONO films and the sacrificial oxide film 5 in the peripheral circuit transistor formation region are removed.

The process from here on is the same as the process shown in FIG. 2E to FIG. 3H of the first embodiment and will therefore not be described.

With this second embodiment, the same effects can be obtained as in the first embodiment.

That is, after ONO films have been formed on the entire surface of the silicon substrate 1 and the ONO films in only the peripheral circuit transistor formation region 4 have been removed, the gate oxide film is formed on the surface of the silicon substrate 1 in the peripheral circuit transistor formation region 4, so that compared to the related art, the process can be shortened, and as a result, the manufacturing cost can be reduced.

Also, in the present embodiment, when dry etching the nitride film 7 in the peripheral circuit transistor formation region, even if holes are produced in the bottom oxide film 6 by a partial etching of the bottom oxide film 6 due to the etching selection ratio not being sufficient, the sacrificial oxide film 5 will remain below the bottom oxide film 6, so that the silicon substrate 1 does not become exposed and etching of the silicon substrate is prevented. By doing so, it is possible to etch the nitride film 7 even if the etching selection ratio is not set sufficiently high. Accordingly, it is possible to set a large margin for the etching conditions, so that the etching process is facilitated.

Also, since the peripheral circuit transistor formation region is covered with the sacrificial oxide film 5 when the ONO films are formed, there is the advantage that the peripheral circuit transistor formation region 4 will hardly be affected by NH₃ and the like, if at all.

It should be noted that the present invention is not limited to the embodiments described above, and can be modified as appropriate without departing from the scope of the present invention.

1. A method of manufacturing a semiconductor device, comprising:
a step of forming a bottom oxide film on a semiconductor substrate, the bottom oxide film being located in a memory transistor formation region and a peripheral circuit transistor formation region;
a step of forming a nitride film on the bottom oxide film;
a step of forming a top oxide film on the nitride film;
a step of removing the top oxide film, the nitride film and the bottom oxide film from the peripheral circuit transistor formation region to expose a surface of the semiconductor substrate in the peripheral circuit transistor formation region; and
a step of forming a gate insulating film on the semiconductor substrate in the peripheral circuit transistor formation region.

2. A method of manufacturing a semiconductor device, comprising:
a step of forming a sacrificial oxide film on a semiconductor substrate, the sacrificial oxide film being located in a memory transistor formation region and a peripheral circuit transistor formation region;
a step of removing the sacrificial oxide film in the memory transistor formation region while leaving the sacrificial oxide film in the peripheral circuit transistor formation region;
a step of forming a bottom oxide film on the semiconductor substrate in the memory transistor formation region and on the sacrificial oxide film in the peripheral circuit transistor formation region;
a step of forming a nitride film on the bottom oxide film;
a step of forming a top oxide film on the nitride film;
a step of etching and removing the top oxide film, etching and removing the nitride film, and etching and removing the bottom oxide film with the sacrificial oxide film from the peripheral circuit transistor formation region to expose a surface of the semiconductor substrate in the peripheral circuit transistor formation region; and
a step of forming a gate insulating film on the semiconductor substrate in the peripheral circuit transistor formation region.

3. The method of manufacturing a semiconductor device according to claim 2, further comprising, between the step of forming the bottom oxide film and the step of forming the nitride film, a step of carrying out a heat treatment in an NH₃ atmosphere.

4. The method of manufacturing a semiconductor device according to claim 2, further comprising a step of forming, after the step of forming the gate insulating film on the semiconductor substrate, a first gate electrode on the top oxide film in the memory transistor formation region and forming a second gate electrode on the gate insulating film in the peripheral circuit transistor formation region.

5. The method of manufacturing a semiconductor device according to claim 2, further comprising a step of forming, after the step of forming the gate insulating film on the semiconductor substrate, a polysilicon film on the top oxide film in the memory transistor formation region and the gate insulating film in the peripheral circuit transistor formation region, respectively, and patterning the polysilicon film to form a first gate electrode composed of the polysilicon film on the top oxide film in the memory transistor formation region, and form a second gate electrode composed of the polysilicon film on the gate insulating film in the peripheral circuit transistor formation region.

6. The method of manufacturing a semiconductor device according to claim 4, further comprising a step of forming, after the step of forming the second gate electrode on the gate insulating film, source and drain regions in the semiconductor substrate on both sides of and below the first gate electrode and the second gate electrode, respectively.

7. The method of manufacturing a semiconductor device according to claim 4, further comprising a step of forming, after the step of forming the second gate electrode on the gate insulating film, LDD regions in the semiconductor substrate on both sides of and below the first gate electrode and the second gate electrode, respectively, and forming source and drain regions in the semiconductor substrate at positions outside the LDD regions.

8. A method of manufacturing a semiconductor device, comprising:
a step of forming ONO films on a semiconductor substrate, the ONO films being located in a memory transistor formation region and a peripheral circuit transistor formation region;
a step of removing the ONO films from the peripheral circuit transistor formation region to expose a surface of the semiconductor substrate in the peripheral circuit transistor formation region; and
a step of forming a gate insulating film on the semiconductor substrate in the peripheral circuit transistor formation region.

9. A method of manufacturing a semiconductor device, comprising:
a step of forming a sacrificial oxide film on a semiconductor substrate, the sacrificial oxide film being located in a memory transistor formation region and a peripheral circuit transistor formation region;
a step of removing the sacrificial oxide film from the memory transistor formation region while leaving the sacrificial oxide film in the peripheral circuit transistor formation region;
a step of forming ONO films on the semiconductor substrate, the ONO films being located in the memory transistor formation region and on the sacrificial oxide film in the peripheral circuit transistor formation region;
a step of etching and removing the ONO films and the sacrificial oxide film in the peripheral circuit transistor formation region to expose a surface of the semiconductor substrate in the peripheral circuit transistor formation region; and
a step of forming a gate insulating film on the semiconductor substrate in the peripheral circuit transistor formation region.

10. The method of manufacturing a semiconductor device according to claim 5, further comprising a step of forming, after the step of forming the second gate electrode on the gate insulating film, source and drain regions in the semiconductor substrate on both sides of and below the first gate electrode and the second gate electrode, respectively.

11. The method of manufacturing a semiconductor device according to claim 5, further comprising a step of forming, after the step of forming the second gate electrode on the gate insulating film, LDD regions in the semiconductor substrate on both sides of and below the first gate electrode and the second gate electrode, respectively, and forming source and drain regions in the semiconductor substrate at positions outside the LDD regions.

12. The method of manufacturing a semiconductor device according to claim 1, further comprising a step of forming, after the step of forming the gate insulating film on the semiconductor substrate, a first gate electrode on the top oxide film in the memory transistor formation region and forming a second gate electrode on the gate insulating film in the peripheral circuit transistor formation region.

13. The method of manufacturing a semiconductor device according to claim 1, further comprising a step of forming, after the step of forming the gate insulating film on the semiconductor substrate, a polysilicon film on the top oxide film in the memory transistor formation region and the gate insulating film in the peripheral circuit transistor formation region, respectively, and patterning the polysilicon film to form a first gate electrode composed of the polysilicon film on the top oxide film in the memory transistor formation region, and form a second gate electrode composed of the polysilicon film on the gate insulating film in the peripheral circuit transistor formation region.

14. The method of manufacturing a semiconductor device according to claim 12, further comprising a step of forming, after the step of forming the second gate electrode on the gate insulating film, source and drain regions in the semiconductor substrate on both sides of and below the first gate electrode and the second gate electrode, respectively.

15. The method of manufacturing a semiconductor device according to claim 12, further comprising a step of forming, after the step of forming the second gate electrode on the gate insulating film, LDD regions in the semiconductor substrate on both sides of and below the first gate electrode and the second gate electrode, respectively, and forming source and drain regions in the semiconductor substrate at positions outside the LDD regions.

16. The method of manufacturing a semiconductor device according to claim 13, further comprising a step of forming, after the step of forming the second gate electrode on the gate insulating film, source and drain regions in the semiconductor substrate on both sides of and below the first gate electrode and the second gate electrode, respectively.

17. The method of manufacturing a semiconductor device according to claim 13, further comprising a step of forming, after the step of forming the second gate electrode on the gate insulating film, LDD regions in the semiconductor substrate on both sides of and below the first gate electrode and the second gate electrode, respectively, and forming source and drain regions in the semiconductor substrate at positions outside the LDD regions.
